(19) United States
(12) Patent Application Publication
(10) Pub. No.: US 2024/0357812 A1
(43) Pub. Date: Oct. 24, 2024

(54) SEMICONDUCTOR DEVICE AND MANUFACTURING METHOD OF A SEMICONDUCTOR DEVICE

(71) Applicant: SK hynix Inc., Icheon-si Gyeonggi-do (KR)

(72) Inventor: Byung Woo KANG, Icheon-si Gyeonggi-do (KR)

(73) Assignee: SK hynix Inc., Icheon-si Gyeonggi-do (KR)

(21) Appl. No.: 18/360,524

(22) Filed: Jul. 27, 2023

(30) Foreign Application Priority Data
Apr. 21, 2023 (KR) 10-2023-0052724

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H01L 24/08; H01L 24/80; H01L 25/0657; H01L 25/18; H01L 25/50; H10B 41/27; H10B 80/00; H01L 2224/08145; H01L 2224/80006; H01L 2224/80895; H01L 2224/80896; H01L 2924/1431; H01L 2924/14511

(57) ABSTRACT

A semiconductor device includes a gate structure including stacked gate lines and having a step structure. The semiconductor device also includes an interlayer dielectric layer covering the step structure and first supports extending through the interlayer dielectric layer and the gate structure. The semiconductor device further includes contact plugs extending through the interlayer dielectric layer and connected to the gate lines exposed through the step structure, respectively. The semiconductor device additionally includes second supports extending through the gate structure, each of the second supports being located between the first supports.

### CROSS-REFERENCE TO RELATED APPLICATION

This application claims priority under 35 U.S.C. § 119 (a) to Korean Patent Application No. 10-2023-0052724 filed on Apr. 21, 2023, in the Korean Intellectual Property Office, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In accordance with an embodiment of the present disclosure, a semiconductor device may include: a gate structure including stacked gate lines and having a step structure; an interlayer dielectric layer covering the step structure; first supports extending through the interlayer dielectric layer and the gate structure; contact plugs extending through the interlayer dielectric layer and connected to the gate lines exposed through the step structure, respectively; and second supports extending through the gate structure, each of the second supports being located between the first supports.

In accordance with an embodiment of the present disclosure, a semiconductor device may include: a gate structure including stacked gate lines; first supports extending into the gate structure through a front surface of the gate structure; contact plugs extending into the gate structure through the front surface of the gate structure, the contact plugs electrically connected to the gate lines, respectively; and second supports extending into the gate structure through a rear surface of the gate structure, each of the second supports being located between the first supports.

In accordance with an embodiment of the present disclosure, a manufacturing method of a semiconductor device may include: forming a stack including first material layers and second material layers that are alternately stacked; forming first supports extending into the stack through a front surface of the stack; forming contact plugs respectively connected to the first material layers through the front surface of the stack; and forming second supports extending into the stack through a rear surface of the stack.

In accordance with an embodiment of the present disclosure, a manufacturing method of a semiconductor device may include: forming, on a substrate, a first wafer including a stack including first material layers and second material layers that are alternately stacked; bonding the first wafer and the second wafer; exposing a rear surface of the stack by removing the substrate; forming first supports extending into the stack through the rear surface; and replacing the first material layers with third material layers.

### BRIEF DESCRIPTION OF THE DRAWINGS

FIGS. 1A to 1D are diagrams illustrating the structure of a semiconductor device in accordance with an embodiment.

FIGS. 2A to 2C are diagrams illustrating the structure of a semiconductor device in accordance with an embodiment.

FIG. 3 is a diagram illustrating the structure of a semiconductor device in accordance with an embodiment.

FIG. 4 is a diagram illustrating the structure of a semiconductor device in accordance with an embodiment.

FIG. 5 is a diagram illustrating the structure of a semiconductor device in accordance with an embodiment.

FIGS. 6A to 6E are diagrams for describing a manufacturing method of a semiconductor device in accordance with an embodiment.

FIGS. 7A to 7J are diagrams for describing a manufacturing method of a semiconductor device in accordance with an embodiment.

FIGS. 8A to 8D are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

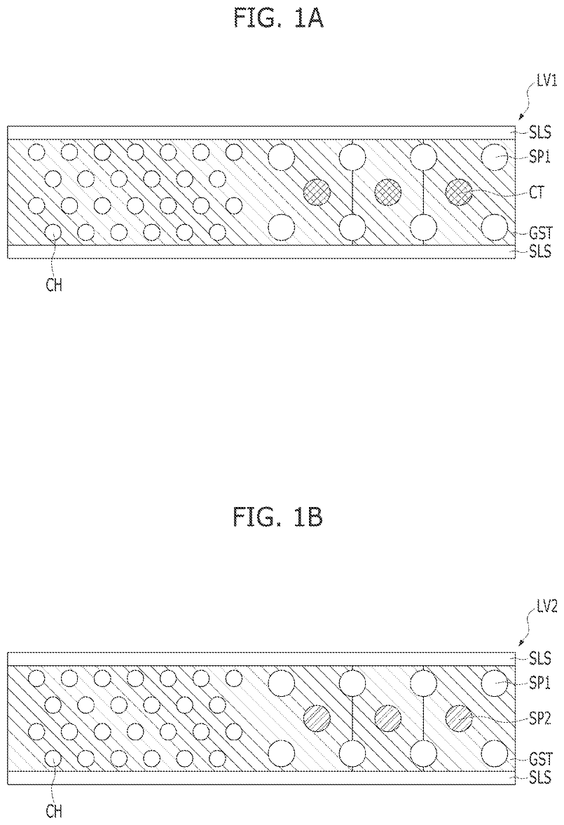

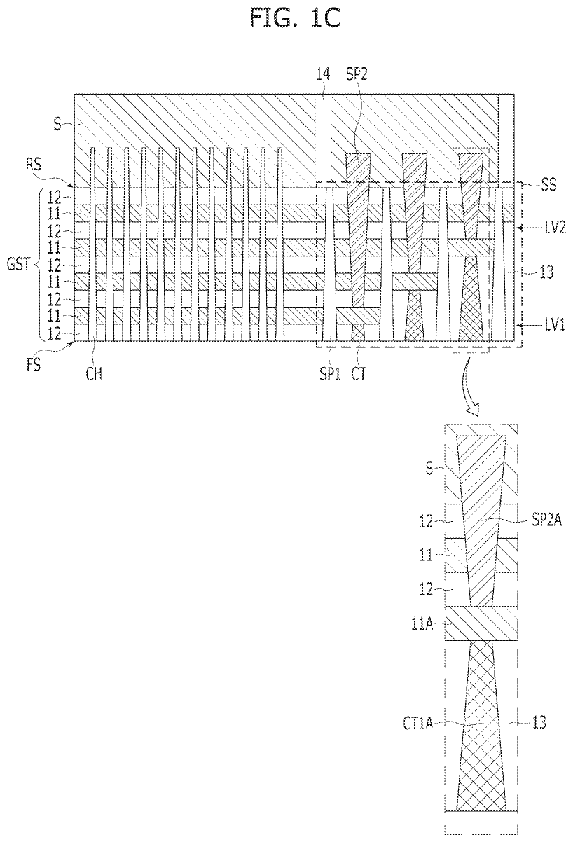

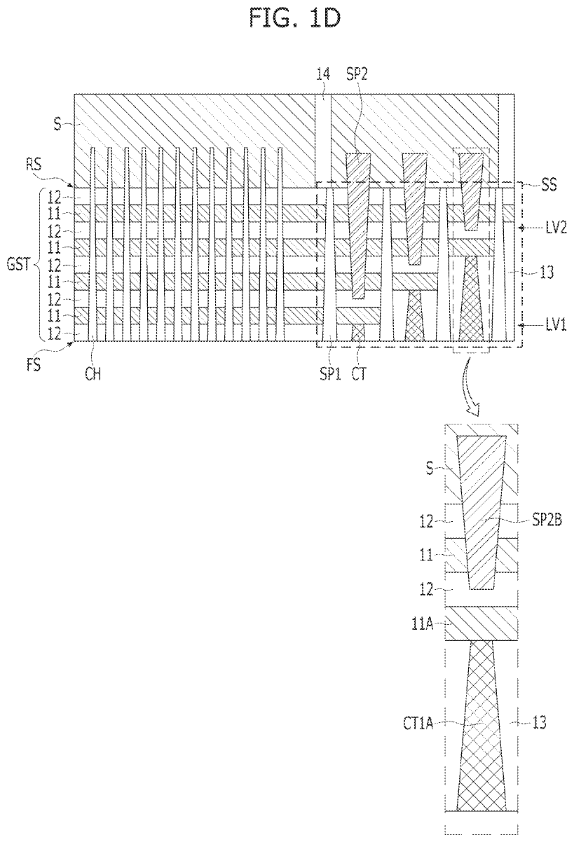

FIGS. 1A to 1D are diagrams illustrating the structure of a semiconductor device in accordance with an embodiment. FIGS. 1C and 1D are cross-sectional views, FIG. 1A is a plan view of a first level LV1 of FIG. 1C or FIG. 1D, and FIG. 1B is a plan view of a second level LV2 of FIG. 1C or FIG. 1D.

Referring to FIGS. 1A to 1D, the semiconductor device may include gate structures GST, an interlayer dielectric layer 13, first supports SP1, contact plugs CT, and second supports SP2. The semiconductor device may further include channel structures CH, source structures S, an insulating layer 14, or a slit structure SLS, or a combination thereof.

The gate structure GST may include stacked gate lines 11. The gate lines 11 may be source select lines, drain select lines, or word lines. As an example, at least one lowermost gate line 11 may be the drain select line, at least one uppermost gate line 11 may be the source select line, and the remaining gate lines 11 may be the word lines. The gate lines 11 may each include a conductive material such as polysilicon, tungsten (W), or molybdenum (Mo). The gate structure GST may include the gate lines 11 and insulating layers 12 that are alternately stacked. The insulating layers 12 are used to insulate the gate lines 11 from each other, and may each include an insulating material such as an oxide, a nitride, or an air gap.

The gate structure GST may include a front surface FS and a rear surface RS. In a manufacturing process, it is common that the rear surface RS is located on a lower side and the front surface FS is located on an upper side; however, when a wafer is reversed, the rear surface RS may be located on the upper side and the front surface FS may be located on the lower side. As an example, the front surface FS may be located on the lower side and the rear surface RS may be located on the upper side, so that the gate structure GST may have a step structure SS in a reversed direction. Also, the front surface FS may be located on the upper side and the rear surface RS may be located on the lower side, and the gate structure GST may have a step structure SS in a forward direction.

The gate structure GST may include at least one step structure SS. Each layer of the step structure SS may include at least one gate line 11 and at least one insulating layer 12. Each of the gate lines 11 may be exposed through at least one step structure SS. A portion of the gate line 11 exposed by the step structure SS may be defined as a pad. The step structure SS may be located on the front surface FS of the gate structure GST.

The interlayer dielectric layer 13 may cover the step structure SS of the gate structure GST. Pads of the gate lines 11 may contact the interlayer dielectric layer 13. The interlayer dielectric layer 13 may be located below the gate structure GST. The interlayer dielectric layer 13 may contact the front surface FS of the gate structure GST.

The source structure S may be located on the gate structure GST. The source structure S may include a conductive material such as polysilicon, tungsten (W), or molybdenum (Mo). The insulating layer 14 may be located between the source structures S, and the source structures S may be insulated from each other by the insulating layer 14. The source structure S and the insulating layer 14 may be located on the rear surface RS of the gate structure GST. The source structure S located on the step structure may be a dummy source structure and may be omitted.

The channel structures CH may extend into the source structure S through the gate structure GST. A memory cell, a source select transistor, or a drain select transistor may be located in a region where the channel structures CH and the gate lines 11 intersect each other.

The slit structure SLS may be located between the gate structures GST and may isolate the gate structures GST from each other. As an example, the slit structure SLS may include an insulating material such as an oxide or a nitride. The slit structure SLS may include a semiconductor material such as a silicon germanium or an amorphous silicon. The semiconductor device may include a source contact structure in which the source contact structure is electrically connected to the source structure S.

The contact plugs CT may extend through the interlayer dielectric layer 13 and be connected to the front surface FS of the gate structure GST. The contact plugs CT may be electrically connected to the gate lines 11 exposed through the step structure SS, respectively. The contact plug CT may be connected to the pad of the gate line 11.

The contact plugs CT may have the same height or different heights. As an example, a contact plug CT closer to the channel structures CH may have a smaller height than the other contact plug CT. Lower surfaces of the contact plugs CT may be located at substantially the same level, and upper surfaces of the contact plugs CT may be located at different levels.

The first supports SP1 may extend through the interlayer dielectric layer 13 and the gate structure GST. The first supports SP1 may extend into the gate structure GST through the front surface FS of the gate structure GST. The first supports SP1 may be located on the step structure SS. The contact plug CT may be located between the first supports SP1.

The second supports SP2 may extend through the gate structure GST. The second supports SP2 may extend into the gate structure GST through the rear surface RS of the gate structure GST. The second supports SP2 may protrude from the rear surface RS and extend into the source structure S. The second supports SP2 may be located between the first supports SP1.

The second supports SP2 may have the same height or different heights. As an example, a second support SP2 closer to the channel structure CH may have a larger height than the other second support SP2. Upper surfaces of the second supports SP2 may be located at substantially the same level, and lower surfaces of the second supports SP2 may be located at different levels.

At least one of the contact plugs CT, the first supports SP1 and the second supports SP2 may have a tapered cross section. The second supports SP2 may each have a tapered shape in a reverse direction with respect to that of the first supports SP1. The width of the second support SP2 may decrease toward the front surface FS, and the width of the first support SP1 may decrease toward the rear surface RS. The second supports SP2 may each have a tapered shape in a reverse direction with respect to that of the contact plugs CT. The width of the second support SP2 may decrease toward the front surface FS, and the width of the contact plug CT may decrease toward the step structure SS.

The second supports SP2 may be located to correspond to the contact plugs CT, respectively. The second supports SP2 may be located on the contact plugs CT, respectively. As an example, a first contact plug CT1A may be electrically connected to a first gate line 11A among the gate lines 11. The first contact plug CT1A and the second supports SP2A and SP2B may face each other with the first gate line 11A interposed therebetween. Referring to FIG. 1C, the first contact plug CT1A may be connected to a lower surface of the first gate line 11A, and the second support SP2A may be connected to an upper surface of the first gate line 11A. Referring to FIG. 1D, the first contact plug CT1A may be connected to the lower surface of the first gate line 11A, and a second support SP2B may be spaced apart from the upper surface of the first gate line 11A.

Because the second supports SP2 are located to correspond to the contact plugs CT, the heights of the contact plugs CT and the second supports SP2 may be relative. In a pair of contact plug CT and second support SP2 located to correspond to each other, when the height of the contact plug CT is high, the height of the second support SP2 may be small. Similarly, in a pair of contact plug CT and second support SP2, when the height of the contact plug CT is small, the height of the second support SP2 may be large.

According to the structure described above, the semiconductor device may include the first supports SP1 and the second supports SP2. The first supports SP1 and the second supports SP2 may be used as supports in a process of replacing sacrificial layers with the gate lines 11. Accordingly, the semiconductor device may have a stable structure.

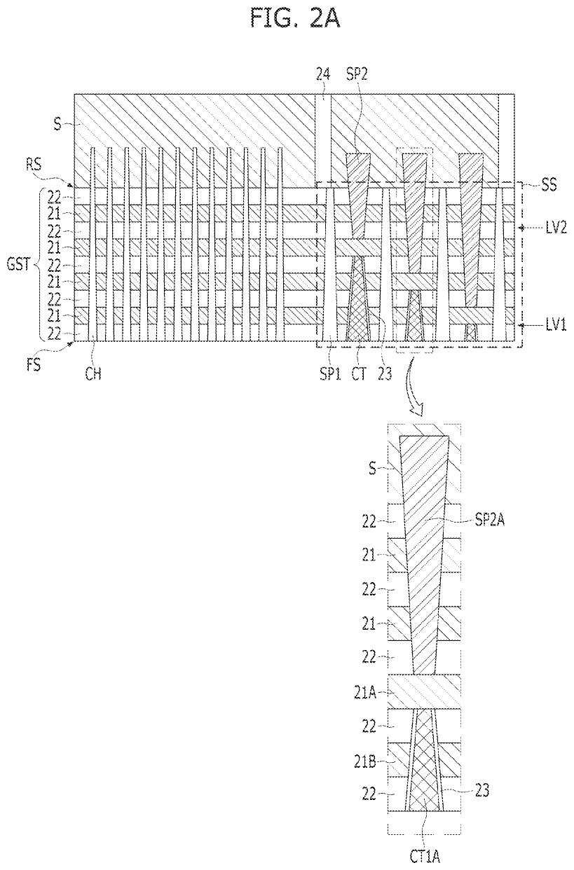

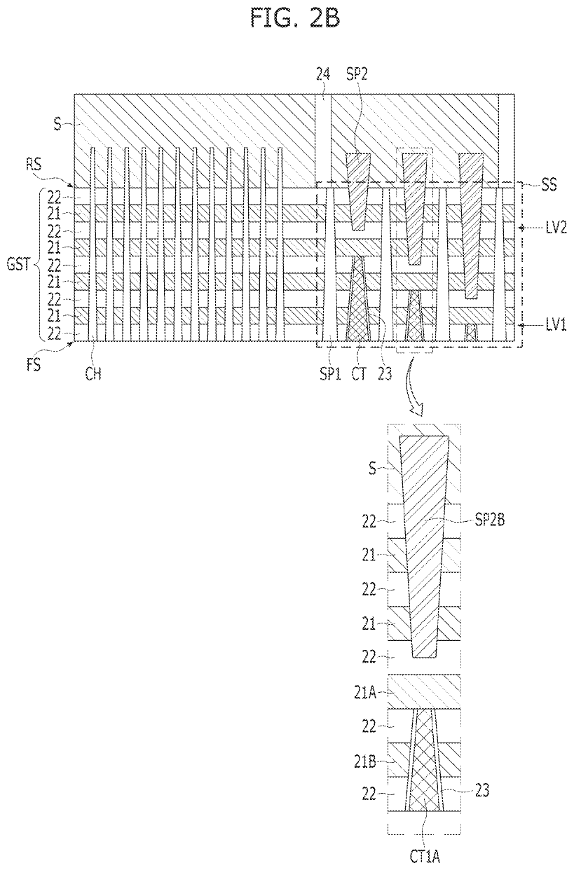

FIGS. 2A to 2C are diagrams illustrating the structure of a semiconductor device in accordance with an embodiment. FIGS. 2A to 2C are cross-sectional views, respectively. Hereinafter, content overlapping with the previously described content will be omitted.

Referring to FIGS. 2A to 2C, the semiconductor device may include a gate structure GST, first supports SP1, contact plugs CT, second supports SP2, channel structures CH, a source structure S, an insulating spacer 23, or an insulating layer 24, or a combination thereof.

The gate structure GST may include stacked gate lines 21. The gate structure GST may include gate lines 21 and insulating layers 22 that are alternately stacked. The gate structure GST may include a front surface FS and a rear surface RS. The front surface FS and the rear surface RS of the gate structure GST may be flat, and may include no step structure.

The source structure S may be located on the gate structure GST. The insulating layer 24 may be located between the source structures S, and the source structures S may be insulated from each other by the insulating layer 24. The source structure S and the insulating layer 24 may be located on the rear surface RS of the gate structure GST. The channel structures CH may extend into the source structure S through the gate structure GST.

The contact plugs CT may extend into the gate structure GST through the front surface FS of the gate structure GST. The contact plugs CT may be electrically connected to the gate lines 21, respectively. The insulating spacers 23 may surround sidewalls of the contact plugs CT. As an example, a first contact plug CT1 among the contact plugs CT may extend through a second gate line 21B and may be connected to a first gate line 21A. The first contact plug CT1 and the second gate line 21B may be insulated by the insulating spacer 23 surrounding sidewalls of the first contact plug CT1.

The first supports SP1 may extend through the gate structure GST. The first supports SP1 may extend into the gate structure GST through the front surface FS of the gate structure GST. The contact plug CT may be located between the first supports SP1.

The second supports SP2 may extend into the gate structure GST through the rear surface RS of the gate structure GST. The second supports SP2 may protrude from the rear surface RS and extend into the source structure S. Each of the second supports SP2 may be located between the first supports SP1.

At least one of the contact plugs CT, the first supports SP1, and the second supports SP2 may have a tapered cross section. The second supports SP2 may each have a tapered shape in a reverse direction with respect to that of the first supports SP1. The width of the second support SP2 may decrease toward the front surface FS, and the width of the first support SP1 may decrease toward the rear surface RS. The second supports SP2 may each have a tapered shape in a reverse direction with respect to that of the contact plugs CT. The width of the second support SP2 may decrease toward the front surface FS, and the width of the contact plug CT may decrease toward the rear surface RS.

The second supports SP2 may be located to correspond to the contact plugs CT, respectively. The second supports SP2 may be located on the contact plugs CT, respectively. As an example, a first contact plug CT1A may be electrically connected to a first gate line 21A among the gate lines 21. The first contact plug CT1A and second supports SP2A and SP2B may face each other with the first gate line 21A interposed therebetween. Referring to FIG. 2A, the first contact plug CT1A may be connected to a lower surface of the first gate line 21A, and the second support SP2A may be connected to an upper surface of the first gate line 21A. Referring to FIG. 2B, the first contact plug CT1A may be connected to the lower surface of the first gate line 21A, and the second support SP2B may be spaced apart from the upper surface of the first gate line 21A.

The contact plugs CT may have the same height or different heights. The second supports SP2 may have the same height or different heights. Referring to FIGS. 2A and 2B, a contact plug CT closer to the channel structure CH may have a larger height than the other contact plug CT. A second support SP2 closer to the channel structure CH may have a smaller height than the other second support SP2. Referring to FIG. 2C, A contact plug CT closer to the channel structures CH may have a smaller height than the other contact plug CT. A second support SP2 closer to the channel structure CH may have a larger height than the other second support SP2.

According to the structure described above, the semiconductor device may include the first supports SP1 and the second supports SP2. The first supports SP1 and the second supports SP2 may be used as supports in a process of replacing sacrificial layers with the gate lines 21. Accordingly, the semiconductor device may have a stable structure.

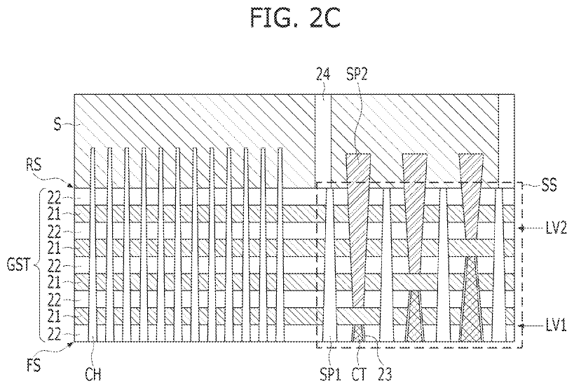

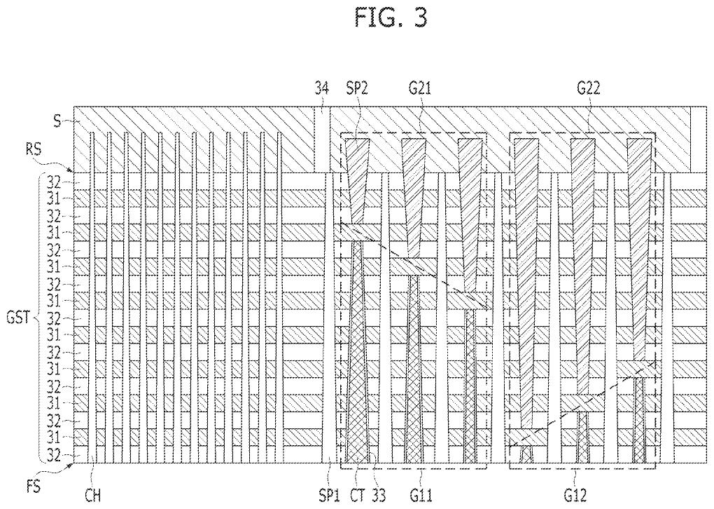

FIG. 3 is a diagram illustrating the structure of a semiconductor device in accordance with an embodiment. FIG. 3 is a cross-sectional view. Hereinafter, content overlapping with the previously described content will be omitted.

Referring to FIG. 3, the semiconductor device may include a gate structure GST, first supports SP1, contact plugs CT, second supports SP2, channel structures CH, source structures S, an insulating spacer 33, or an insulating layer 34, or a combination thereof.

The gate structure GST may include stacked gate lines 31. The gate structure GST may include gate lines 31 and insulating layers 32 that are alternately stacked. The gate structure GST may include a front surface FS and a rear surface RS. The front surface FS and the rear surface RS of the gate structure GST may be flat, and the gate structure GST may include no step structure.

The source structure S may be located on the gate structure GST. The insulating layer 34 may be located between the source structures S, and the source structures S may be insulated from each other by the insulating layer 34. The source structure S and the insulating layer 34 may be located on the rear surface RS of the gate structure GST. The channel structures CH may extend into the source structure S through the gate structure GST.

The contact plugs CT may extend into the gate structure GST through the front surface FS of the gate structure GST. The contact plugs CT may be electrically connected to the gate lines 31, respectively. The insulating spacers 33 may surround sidewalls of the contact plugs CT. The insulating spacers 33 may be located between sidewalls of the contact plugs CT and the gate lines 31.

The first supports SP1 may extend into the gate structure GST through the front surface FS of the gate structure GST. The contact plug CT may be located between the first supports SP1. The second supports SP2 may extend into the gate structure GST through the rear surface RS of the gate structure GST. The second supports SP2 may protrude from the rear surface RS and extend into the source structure S. Each of the second supports SP2 may be located between the first supports SP1. At least one of the contact plugs CT, the first supports SP1, and the second supports SP2 may have a tapered cross section.

The contact plugs CT may have different heights. The contact plugs CT may be arranged in order according to height or may be randomly arranged regardless of height. An arrangement method of the contact plugs CT may be determined in consideration of a layout of wiring lines. As an example, the contact plugs CT may include a first group G11 and a second group G12. In the first group G11, a contact plug CT closer to the channel structure CH may have a higher height than the other contact plug CT. In the second group G12, a contact plug CT closer to the channel structure CH may have a smaller height than the other contact plug CT. The first group G11 may be closer to the channel structures CH than the second group G12, or the second group G12 may be closer to the channel structures CH than the first group G11.

The second supports SP2 may have different heights. The second supports SP2 may be arranged in an order according to height or may be randomly arranged regardless of the order according to height. As an example, the second supports SP2 may include a first group G21 and a second group G22. In the first group G21, a contact plug CT closer to the channel structure CH may have a smaller height than the other contact plug CT. In the second group G22, the contact plug CT closer to the channel structure CH may have a greater height than the other contact plug CT. The first group G21 may be closer to the channel structures CH than the second group G22, or the second group G22 may be closer to the channel structures CH than the first group G21.

According to the structure described above, the semiconductor device may include the first supports SP1 and the second supports SP2. The first supports SP1 and the second supports SP2 may be used as supports in a process of replacing sacrificial layers with the gate lines 31. Accordingly, the semiconductor device may have a stable structure. Furthermore, by arranging the contact plugs CT in consideration of the layout of wiring lines, the wiring lines can be efficiently arranged.

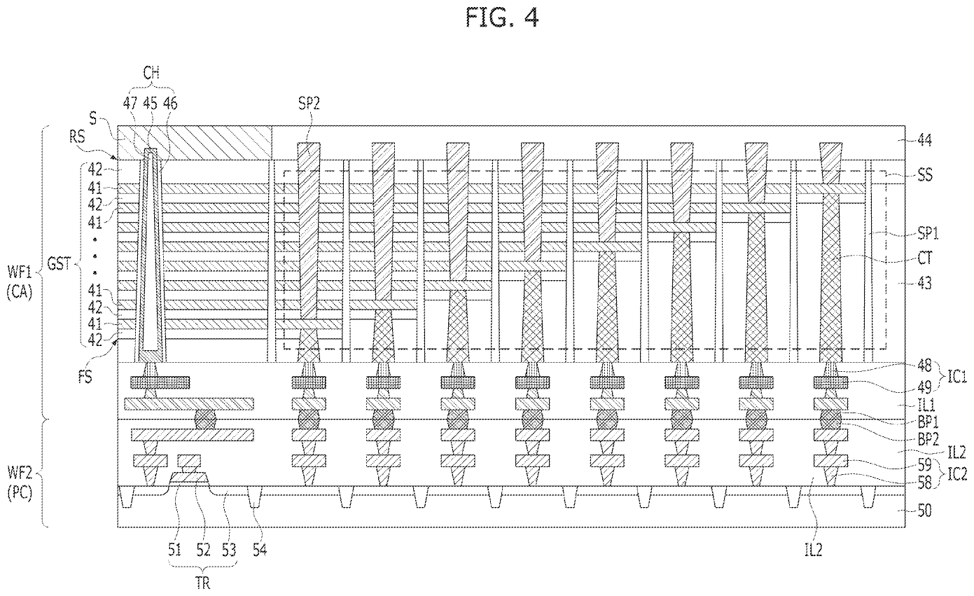

FIG. 4 is a diagram illustrating the structure of a semiconductor device in accordance with an embodiment. FIG. 4 is a cross-sectional view. Hereinafter, content overlapping with the previously described content will be omitted.

Referring to FIG. 4, the semiconductor device may include a first wafer WF1 and a second wafer WF2. The first wafer WF1 may include a cell array CA, and the second wafer WF2 may include a peripheral circuit PC for driving the cell array CA. The first wafer WF1 and the second wafer WF2 may be electrically connected to each other through a first bonding pad BP1 and a second bonding pad BP2. At least one of the first wafer WF1 and the second wafer WF2 might not include a substrate. As an example, after bonding the first wafer WF1 and the second wafer WF2, a substrate of the first wafer WF1 may be removed. The substrate may be completely removed or a partially removed from the first wafer WF1. The first wafer WF1 might not include the substrate or may include a part of the substrate. A substrate of at least one of the first wafer WF1 and the second wafer WF2 may be formed after the bonding of the first wafer WF1 and the second wafer WF2. As an example, a source structure S, a metal layer, etc. may serve as the substrate.

The semiconductor device may include a gate structure GST, first supports SP1, contact plugs CT, second supports SP2, channel structures CH, a source structure S, an interlayer dielectric layer 43, an insulating layer 44, a first interlayer insulating layer IL1, a first interconnection structure IC1, the first bonding pad BP1, a substrate 50, an isolation layer 54, a transistor TR, a second interlayer dielectric layer IL2, a second interconnection structure IC2, and the second bonding pad BP2, or a combination thereof. The gate structure GST, the first supports SP1, the contact plugs CT, the second supports SP2, the channel structures CH, the source structure S, the interlayer dielectric layer 43, the insulating layer 44, the first interlayer dielectric layer IL1, the first interconnection structure IC1, and the first bonding pad BP1 may belong to the first wafer WF1. The substrate 50, the isolation layer 54, the transistor TR, the second interlayer dielectric layer IL2, the second interconnection structure IC2, and the second bonding pad BP2 may belong to the second wafer WF2.

The gate structure GST may include stacked gate lines 41. The gate structure GST may include the gate lines 41 and insulating layers 42 that are alternately stacked. The gate structure GST may include a front surface FS and a rear surface RS. The gate structure GST may include a step structure SS, and the gate lines 41 may be exposed through the step structure SS, respectively. The source structure S and the insulating layer 44 may be located on the rear surface RS of the gate structure GST. The source structure S may serve as the substrate. The channel structures CH may extend into the source structure S through the gate structure GST.

The contact plugs CT may be electrically connected to the gate lines 41 through the front surface FS of the gate structure GST, respectively. Each of the gate lines 41 may be exposed through the step structure SS, and the contact plugs CT may be connected to the gate lines 41 through the interlayer dielectric layer 43, respectively.

The first supports SP1 may extend into the gate structure GST through the interlayer dielectric layer 43 and the front surface FS of the gate structure GST. The contact plug CT may be located between the first supports SP1. The second supports SP2 may extend into the gate structure GST through the rear surface RS of the gate structure GST. The second supports SP2 may protrude from the rear surface RS and extend into the source structure S. Each of the second supports SP2 may be located between the first supports SP1. At least one of the contact plugs CT, the first supports SP1, and the second supports SP2 may have a tapered cross section.

The channel structures CH may extend into the source structure S through the gate structure GST. The channel structure CH may include a channel layer 45. The channel structure CH may further include a memory layer 46 surrounding the channel layer 45 or an insulating core 47 in the channel layer 45, or a combination thereof. The memory layer 46 may include a tunneling layer, a data storage layer, or a blocking layer, or a combination thereof. The data storage layer may include a floating gate, polysilicon, a charge trap material, a nitride, a variable resistance material, or the like, or a combination thereof.

The first interconnection structure IC1 may be electrically connected to the channel structure CH or the contact plugs CT. The first interconnection structure IC1 may be located in the first interlayer dielectric layer IL1 and may include vias 48, wiring lines 49, and the like.

The isolation layer 54 may be located in the substrate 50, and the transistor TR may be located in an active region defined by the isolation layer 54. The transistor TR may include a gate insulating layer 51, a gate electrode 52, and a junction 53. The transistor TR may belong to the peripheral circuit PC. As an example, the peripheral circuit PC may include a row decoder, a page buffer, and the like.

The second interconnection structure IC2 may be electrically connected to the peripheral circuit PC. The second interconnection structure IC2 may be located in the second interlayer dielectric layer IL2, and may include vias 58, wiring lines 59, and the like.

According to the structure described above, the cell array CA and the peripheral circuit PC may be distributedly disposed on the first wafer WF1 and the second wafer WF2, respectively. Accordingly, the degree of integration of the semiconductor device can be improved. The semiconductor device may further include the first supports SP1 and the second supports SP2. The first supports SP1 and the second supports SP2 may be used as supports in a process of replacing sacrificial layers with the gate lines 41. Accordingly, the semiconductor device may have a stable structure.

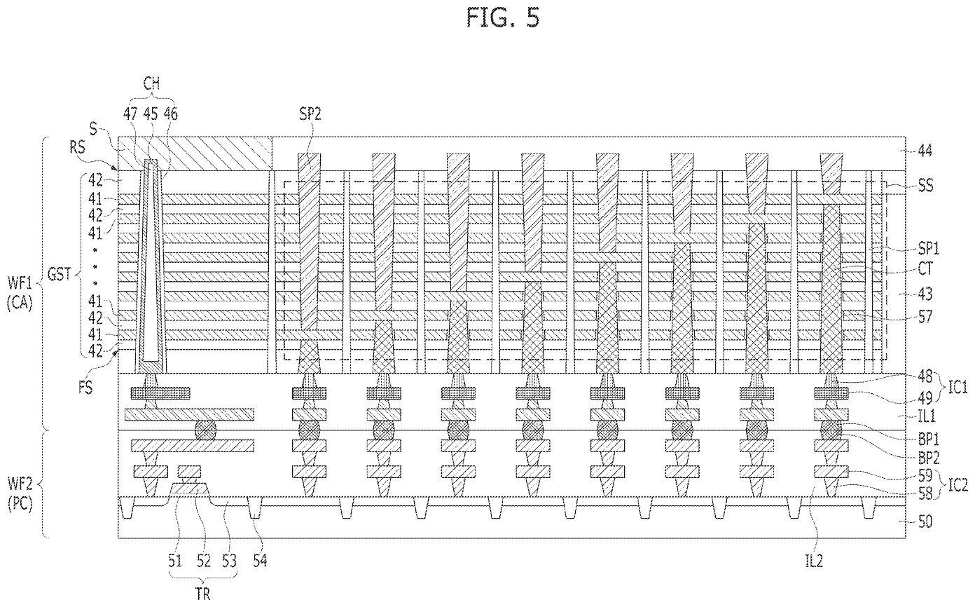

FIG. 5 is a diagram illustrating the structure of a semiconductor device in accordance with an embodiment. FIG. 5 is a cross-sectional view. Hereinafter, content overlapping with the previously described content will be omitted.

Referring to FIG. 5, the semiconductor device may include a first wafer WF1 and a second wafer WF2. The first wafer WF1 may include a cell array CA, and the second wafer WF2 may include a peripheral circuit PC for driving the cell array CA. The first wafer WF1 and the second wafer WF2 may be electrically connected to each other through a first bonding pad BP1 and a second bonding pad BP2.

The semiconductor device may include a gate structure GST, first supports SP1, contact plugs CT, second supports SP2, channel structures CH, insulating spacers 57, a source structure S, an interlayer dielectric layer 43, an insulating layer 44, a first interlayer insulating layer IL1, a first interconnection structure IC1, the first bonding pad BP1, a substrate 50, an isolation layer 54, a transistor TR, a second interlayer dielectric layer IL2, a second interconnection structure IC2, and the second bonding pad BP2, or a combination thereof. The gate structure GST, the first supports SP1, the contact plugs CT, the second supports SP2, the channel structures CH, the insulating spacers 57, the source structure S, the interlayer dielectric layer 43, The insulating layer 44, the first interlayer dielectric layer IL1, the first interconnection structure IC1, and the first bonding pad BP1 may belong to the first wafer WF1. The substrate 50, the isolation layer 54, the transistor TR, the second interlayer dielectric layer IL2, the second interconnection structure IC2, and the second bonding pad BP2 may belong to the second wafer WF2.

The gate structure GST may include stacked gate lines 41. The gate structure GST may include gate lines 41 and insulating layers 42 alternately stacked. The gate structure GST may include a front surface FS and a rear surface RS. The front surface FS and rear surface RS of the gate structure GST may be flat, and the gate structure GST may include no step structure. The source structure S and the insulating layer 44 may be located on the rear surface RS of the gate structure GST. The channel structures CH may extend into the source structure S through the gate structure GST.

The contact plugs CT may be electrically connected to the gate lines 41 through the front surface FS of the gate structure GST, respectively. The contact plugs CT may extend into the gate structure GST through the front surface FS of the gate structure GST. The insulating spacers 57 may surround sidewalls of the contact plugs CT. The insulating spacers 57 may be located between the sidewalls of the contact plugs CT and the gate lines 41, respectively.

The first supports SP1 may extend into the gate structure GST through the interlayer dielectric layer 43 and the front surface FS of the gate structure GST. The contact plug CT may be located between the first supports SP1. The second supports SP2 may extend into the gate structure GST through the rear surface RS of the gate structure GST. The second supports SP2 may protrude from the rear surface RS and extend into the source structure S. Each of the second supports SP2 may be located between the first supports SP1. At least one of the contact plugs CT, the first supports SP1, and the second supports SP2 may have a tapered cross section.

According to the structure as described above, the cell array CA and the peripheral circuit PC may be distributedly disposed on the first wafer WF1 and the second wafer WF2. Accordingly, the degree of integration of the semiconductor device can be improved. Furthermore, the semiconductor device may include first supports SP1 and second supports SP2. The first supports SP1 and the second supports SP2 may be used as supports in a process of replacing the sacrificial layers with the gate lines 41. Thus, the semiconductor device may have a stable structure.

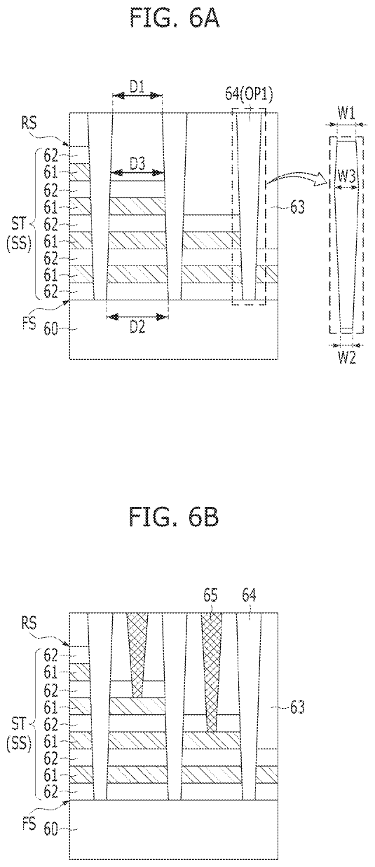

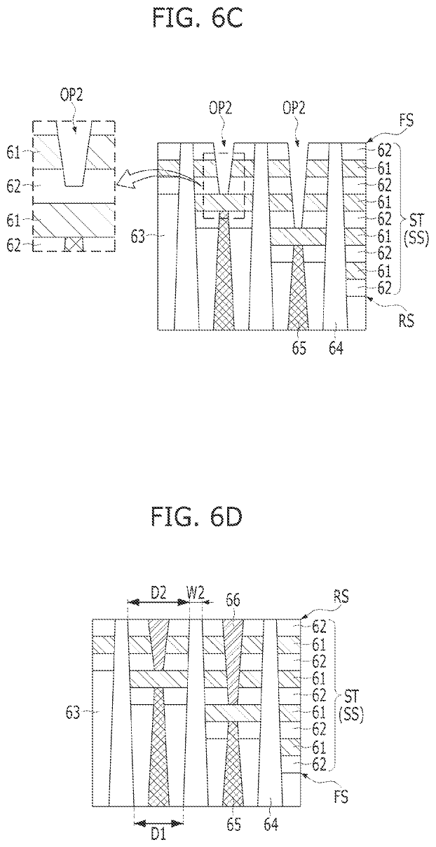

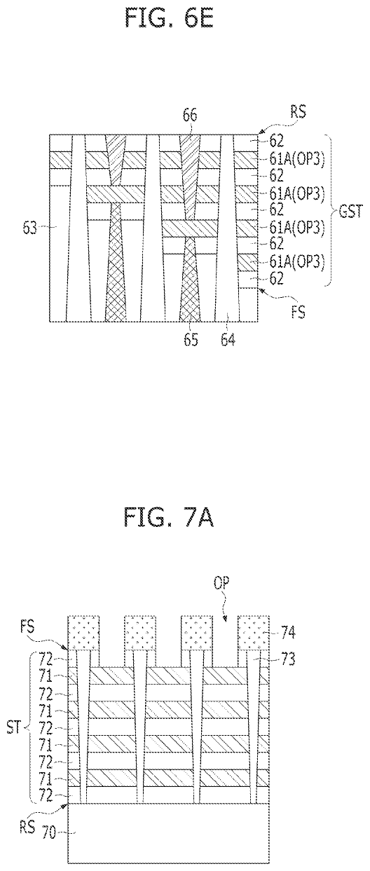

FIGS. 6A to 6E are diagrams for describing a manufacturing method of a semiconductor device in accordance with an embodiment. Hereinafter, content overlapping with the previously described content will be omitted.

Referring to FIG. 6A, a stack ST may be formed. The stack ST may be located on a substrate 60 and may include first material layers 61 and second material layers 62 that are alternately stacked. The first material layers 61 may be used to form gate lines, and the second material layers 62 may be used to insulate stacked gate lines from each other. The first material layers 61 may each include a material having a high etching selectivity with respect to the second material layers 62. For example, the first material layers 61 may each include a sacrificial material such as a nitride, and the second material layers 62 may each include an insulating material such as an oxide. As another example, the first material layers 61 may each include a conductive material such as polysilicon, tungsten (W), or molybdenum (Mo), and the second material layers 62 may each include an insulating material such as an oxide.

Subsequently, a step structure SS may be formed. As an example, at least one step structure SS may be formed by partially patterning the stack ST. The step structure SS may be formed on a front surface FS of the stack ST. Each of the first material layers 61 may be exposed through the step structure SS. Subsequently, an insulating layer 63 may be formed on the stack ST. The insulating layer 63 may cover the step structure SS.

Subsequently, first supports 64 may be formed. The first supports 64 may extend into the stack ST through the insulating layer 64. The first supports 64 may extend into the stack ST through the front surface FS of the stack ST. The first supports 64 may each include a material having a high etching selectivity with respect to the first material layers 61. As an example, the first material layers 61 may each include a nitride, and the first supports 64 may each include an oxide.

As an example, after a first opening OP1 is formed by etching the stack ST, the first support 64 may be formed in the first opening OP1. The first opening OP1 may have a shape with a high aspect ratio, and may have different widths according to levels due to limitations of an etching process. An upper surface of the first opening OP1 may have a first width W1, and a lower surface of the first opening OP1 may have a second width W2. The second width W2 may be smaller than the first width W1, and the first support 64 may have a tapered cross section. The first opening OP1 may have a third width W3 between the upper surface and the lower surface. The third width W3 may be larger than the first width W1 and the second width W2, and the first opening OP1 may have a bowing cross section. The shape of the first opening OP1 may be transferred to the first supports 64, and the first supports 64 may each have a tapered or bowing cross section. The first supports 64 may each have a lower width smaller than the upper width or a middle width larger than the upper width and the lower width.

Distances D1 and D2 between the first supports 64 may be different according to levels. Upper surfaces of the first supports 64 may be spaced apart from each other by a first distance D1, and lower surfaces of the first supports 64 may be spaced apart from each other by a second distance D2. The second distance D2 may be greater than the first distance D1. The first supports 64 may be spaced apart from each other by a third distance D3 between the upper surface and the lower surface. As an example, when the first supports 64 each have a tapered shape, the first distance D1 may be smaller than the second distance D2. As an example, when the first supports 64 have a bowing shape, the third distance D3 may be smaller than the first distance D1 and the second distance D2.

When the distance between the first supports 64 is small, defects such as interconnection of adjacent first openings OP1 may occur in the process of forming the first openings OP1. Accordingly, the distance between the first openings OP1 may be determined in consideration of the shapes of the first openings OP1. When the first openings OP1 have non-uniform widths, the distance between the first openings OP1 may be determined by considering a maximum width of the first openings OP1 so that adjacent first openings OP1 do not overlap each other.

Referring to FIG. 6B, contact plugs 65 may be formed. The contact plugs 65 may be connected to the stack ST through the insulating layer 63. The contact plugs 65 may be connected to the first material layers 61 through a front surface of the stack ST, respectively. The contact plugs 65 may be located between the first supports 64. The contact plugs 65 may each have a tapered cross section. The contact plugs 65 may each have a lower width smaller than an upper width.

Referring to FIG. 6C, the substrate 60 may be removed. As an example, the substrate 60 may be removed after an intermediate product is reversed so that the substrate 60 is located on the stack ST. The substrate 60 may be removed using a grinding process, a planarization process, an etching process, or the like. Through this, a rear surface of the stack ST may be exposed.

Referring to FIGS. 6C and 6D, second supports 66 may be formed. The second supports 66 may extend into the stack ST through the rear surface RS of the stack ST. The second supports 66 may be used to reinforce the bearing capacity of the stack ST in a subsequent process. The second supports 66 may have a tapered or bowing cross section. The second supports 66 may each have a lower width smaller than an upper width. The second supports 66 may be located above the contact plugs 65, respectively. The second supports 66 may be located to face the contact plug 65 with at least one first material layer 61 interposed therebetween. The second supports 66 may each include a material having a high etching selectivity with respect to the first material layers 61. As an example, the first material layers 61 may each include a nitride, and the second supports 66 may each include an oxide.

First, referring to FIG. 6C, second openings OP2 extending from the rear surface RS of the stack ST into the stack ST may be formed. The second openings OP2 may have substantially the same depth or different depths. The second openings OP2 may extend between the first supports 64 and may have depths such that the contact plugs 65 are not exposed. As an example, the second opening OP2 may be formed with a depth such that a surface of the first material layer 61, to which the contact plug 65 is connected, is exposed. As an example, the second opening OP2 may pass through the remaining first material layers 61 except for the first material layer 61 to which the contact plug 65 is connected, and may be formed with a depth such that the surface of the first material layer 61, to which the contact plug 65 is connected, is not exposed (see an enlarged view). Referring to FIG. 6D, the second supports 66 may be formed in the second openings OP2, respectively.

As the height of the stack ST increases, an aspect ratio of the first support 64 may increase and the maximum width of the first support 64 may increase. Accordingly, the distances D1 and D2 between the first supports 64 may be increased in order to prevent overlap between adjacent first supports 64. As the aspect ratio of the first support 64 increases, the second width W2 may be decreased and the second distance D2 may be increased due to process limitations.

When the second distance D2 increases, the bearing capacity of the stack ST may be decreased in a subsequent process. The stack ST may be tilted or collapsed between the first supports 64. Accordingly, the second supports 66 may be additionally formed between the first supports 64. Because the second supports 66 extend into the stack ST from the rear surface of the stack ST, it is possible to reinforce weakened bearing capacity between the first supports 64.

Referring to FIG. 6E, the first material layers 61 may be replaced with third material layers 61A, respectively. Through this, a gate structure GST including third material layers 61A and second material layers 62 that are alternately stacked may be formed. As an example, after a slit is formed in the stack ST, third openings OP3 may be formed by removing the first material layers 61 through the slit. When the first material layers 61 are removed, the first material layers 61 may be selectively etched, and the third openings OP3 may be formed between the second material layers 62. In this case, the first supports 64 and the second supports 66 may support remaining second material layers 62. Subsequently, the third material layers 61A may be formed in the third openings OP3, respectively. The third material layers 61A may each include a metal such as tungsten (W) or molybdenum (Mo). Subsequently, a slit structure may be formed in the slit.

When the first material layers 61 each include a conductive material, the third material layers 61A may be formed by reducing the resistivity of the first material layers 61 through a silicidation process or the like. Alternatively, the first material layers 61 may be used as the third material layers 61A, and the stack ST may be used as the gate structure GST.

According to the manufacturing method described above, the first supports 64 may be formed through the front surface FS of the stack ST, and the second supports 66 may be formed through the rear surface RS of the stack ST. Accordingly, when the first material layers 61 are replaced with the third material layers 61A, inclination or collapse of the stack ST may be reduced.

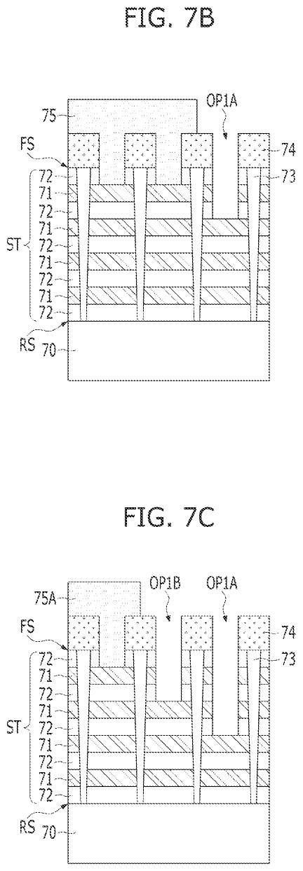

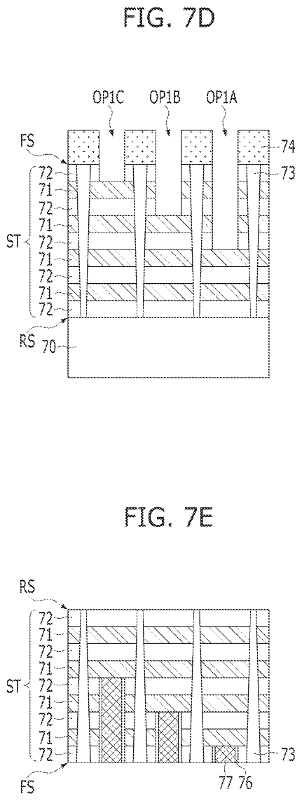

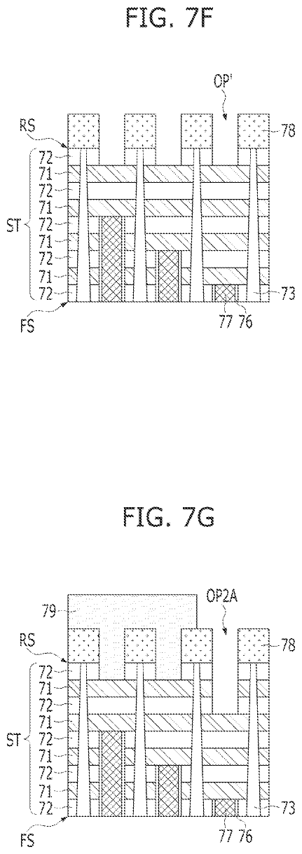

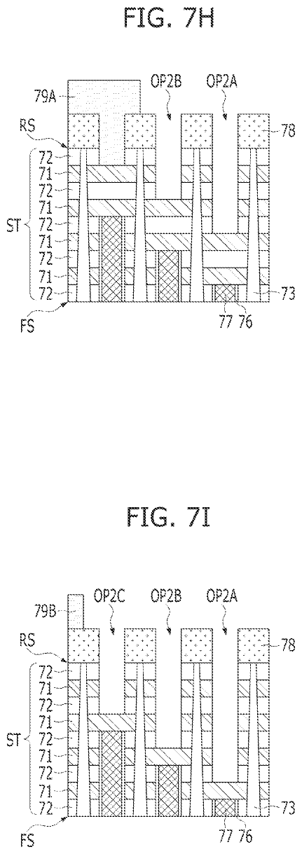

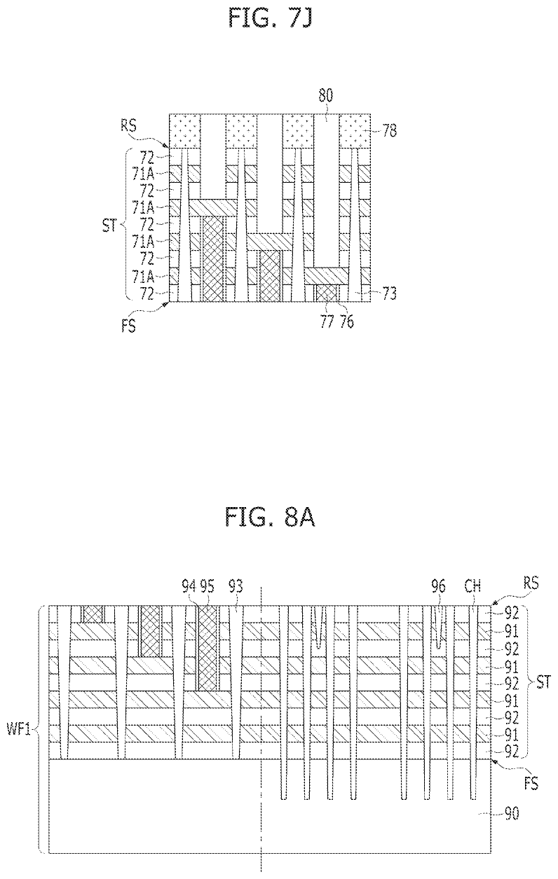

FIGS. 7A to 7J are diagrams for describing a manufacturing method of a semiconductor device in accordance with an embodiment. Hereinafter, content overlapping with the previously described content will be omitted.

Referring to FIG. 7A, a stack ST may be formed. The stack ST may be located on a substrate 70 and may include first material layers 71 and second material layers 72 that are alternately stacked. As an example, the first material layers 71 may each include a sacrificial material such as a nitride, and the second material layers 72 may each include an insulating material such as an oxide.

Subsequently, first supports 73 may be formed. The first supports 73 may extend into the stack ST through a front surface FS of the stack ST. Subsequently, a first hard mask pattern 74 may be formed on the stack ST. The first hard mask pattern 74 may be formed on the front surface FS of the stack ST. The first hard mask pattern 74 may include openings OP, and the openings OP may expose regions where contact plugs are to be formed. As an example, a hard mask layer may be formed on the front surface FS of the stack ST, and the first hard mask pattern 74 including the openings OP may be formed by etching the hard mask layer. When the hard mask layer is etched, the stack ST may be partially etched.

Referring to FIG. 7B, a first mask 75 may be formed on the first hard mask pattern 74. The first mask 75 may include photoresist. The first mask 75 may be formed to expose at least one of the openings OP. Subsequently, first opening OP1A may be formed by etching the stack ST using the first mask 75 and the first hard mask pattern 74 as etching barriers.

Referring to FIG. 7C, the first mask 75 may be reduced. As the first mask 75 is reduced, the number of exposed openings OP may be increased. Subsequently, the stack ST may be etched using the reduced first mask 75A and the first hard mask pattern 74 as etching barriers. Through this, the first opening OP1A may be extended into the stack ST. A first opening OP1B may be additionally formed in the stack ST.

Referring to FIG. 7D, the process of reducing the first mask 75A and etching the stack ST may be repeatedly performed according to the number of first material layers 71 included in the stack ST. Through this, the first openings OP1A, OP1B, and OP1C may be extended into the stack ST, and the first material layers 71 may be exposed through the first openings OP1A, OP1B, and OP1C, respectively. Subsequently, the first mask 75A may be removed.

Referring to FIG. 7E, contact plugs 77 may be formed in the first openings OP1A, OP1B, and OP1C, respectively. As an example, insulating spacers 76 may be formed in the first openings OP1A, OP1B, and OP1C, respectively, and the contact plugs 77 may be formed in the insulating spacers 76, respectively. Sacrificial layers may also be formed in the first openings OP1A, OP1B, and OP1C, respectively. Subsequently, the substrate 70 may be removed. As an example, the substrate 70 may be removed after an intermediate product is reversed so that the substrate 70 is located on the stack ST. Through this, a rear surface RS of the stack ST may be exposed.

Referring to FIG. 7F, a second hard mask pattern 78 may be formed on the stack ST. The second hard mask pattern 78 may be formed on the rear surface RS of the stack ST. The second hard mask pattern 78 may include openings OP′, and the openings OP′ may expose regions where second supports are to be formed.

Referring to FIG. 7G, a second mask 79 may be formed on the second hard mask pattern 78. The second mask 79 may include photoresist. The second mask 79 may be formed to expose at least one of the openings OP′. Subsequently, a second opening OP2A may be formed by etching the stack ST using the second mask 79 and the second hard mask pattern 78 as etching barriers.

Referring to FIGS. 7H and 7I, a process of reducing the second mask 79 and etching the stack ST using the reduced second masks 79A and 79B and the second hard mask pattern 78 as etching barriers may be repeatedly performed. Through this, the second openings OP2A, OP2B, and OP2C may be formed and may extend into the stack ST. The second openings OP2A, OP2B, and OP2C may have different depths. As an example, the second openings OP2A, OP2B, and OP2C may expose the first material layers 71, respectively.

Referring to FIG. 7J, second supports 80 may be formed in the second openings OP2A, OP2B, and OP2C, respectively. The second supports 80 may extend into the stack ST through the second hard mask pattern 78.

Subsequently, the first material layers 71 may be replaced with third material layers 71A. Through this, a gate structure GST including the third material layers 71A and the second material layers 72 that are alternately stacked may be formed. When sacrificial layers are formed in the first openings OP1A, OP1B, and OP1C, respectively, the sacrificial layers may be removed, and the insulating spacers 76 and the contact plugs 77 may be formed.

According to the manufacturing method described above, the first supports 73 may be formed through the front surface FS of the stack ST, and the second supports 80 may be formed through the rear surface RS of the stack ST. Accordingly, when the first material layers 71 are replaced with the third material layers 71A, inclination or collapse of the stack ST may be reduced.

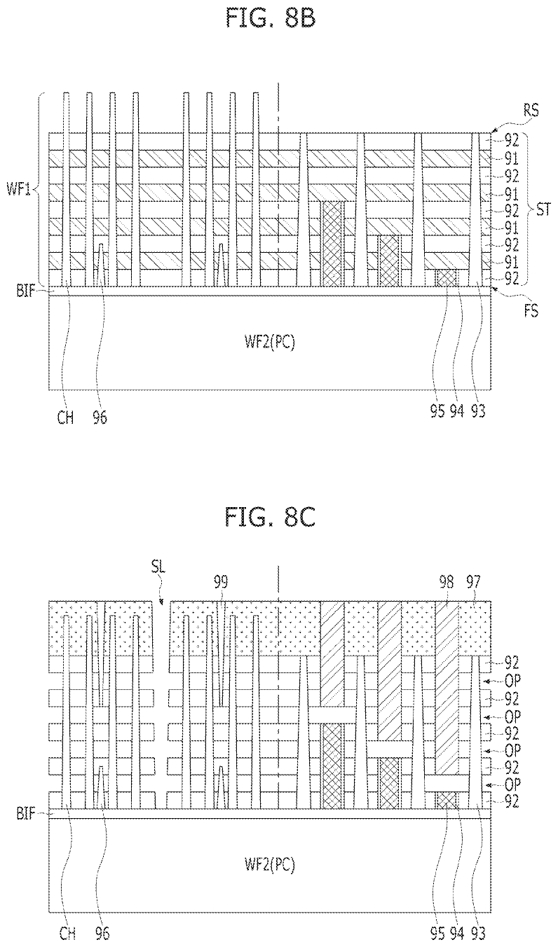

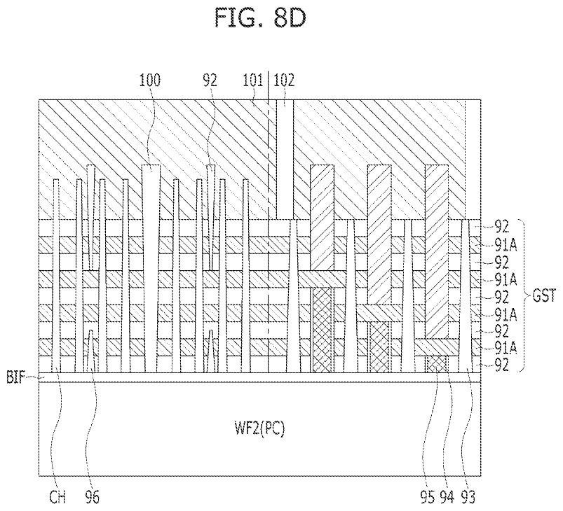

FIGS. 8A to 8D are diagrams for describing a manufacturing method of a semiconductor device in accordance with an embodiment. Hereinafter, content overlapping with the previously described content will be omitted.

Referring to FIG. 8A, a first wafer WF1 including the stack ST may be formed. The first wafer WF1 may include a substrate 90, a stack ST, channel structures CH, a first isolation structure 96, a first support 93, an insulating spacer 94, or a contact plug 95, or a combination thereof.

First, the stack ST may be formed. The stack ST may be located on the substrate 90 and may include first material layers 91 and second material layers 92 that are alternately stacked. As an example, the first material layers 91 may each include a sacrificial material such as a nitride, and the second material layers 92 may each include an insulating material such as an oxide.

The channel structures CH may be formed in the stack ST. The channel structures CH may extend into the substrate 90 through the stack ST. First supports 93 may be formed in the stack ST. The first supports 93 may extend into the stack ST through a front surface FS of the stack ST. The channel structures CH and the first supports 93 may be simultaneously formed or may be formed in separate processes.

The first isolation structure 96 may be formed in the stack ST. The first isolation structure 96 may be used to isolate drain select lines located at the same level. The first isolation structure 96 may have a depth enough for passing through at least one uppermost first material layer 91.

The contact plugs 95 may be formed in the stack ST. The contact plugs 95 may have different heights and may be connected to the first material layers 91, respectively. The insulating spacers 94 may surround sidewalls of the contact plugs 95, respectively. Sacrificial layers may be formed instead of the contact plugs 95 and the insulating spacers 94.

Subsequently, although not illustrated in the drawing, an interconnection structure connected to the channel structures CH, an interconnection structure connected to the contact plugs 95, bonding pads, and the like may be formed. The interconnection structures may include vias, wire lines, and the like.

Referring to FIG. 8B, a second wafer WF2 including a peripheral circuit PC may be formed. Subsequently, the first wafer WF1 and the second wafer WF2 may be bonded to each other. The first wafer WF1 and the second wafer WF2 may be bonded to each other through a bonding interface BIF. As an example, the first wafer WF1 may be reversed and bonded to the second wafer WF2, and the substrate 90 of the first wafer WF1 may be exposed. Subsequently, the substrate 90 may be removed. Through this, a rear surface RS of the stack ST may be exposed. The channel structures CH may protrude from the rear surface RS of the stack ST.

Referring to FIG. 8C, a hard mask pattern 97 may be formed on the stack ST. The hard mask pattern 97 may be formed on the rear surface RS of the stack ST. By repeatedly performing an etching process using the hard mask pattern 97, second supports 98 having different depths may be formed. The second supports 98 may extend into the stack ST through the rear surface RS of the stack ST.

A second isolation structure 99 may be formed in the stack ST. The second isolation structure 99 may be used to isolate source select lines located at the same level. The second isolation structure 99 may extend into the stack ST through the rear surface RS of the stack ST. The second isolation structure 99 may have a depth enough for passing through at least one uppermost first material layer 91.

Subsequently, a slit SL may be formed in the stack ST, and openings OP may be formed by removing the first material layers 91 through the slit SL. Remaining second material layers 92 may be supported by at least one of the first supports 93, the second supports 98, the contact plugs 95, the channel structures CH, the first isolation structure 96, or the second isolation structure 99.

Referring to FIG. 8D, third material layers 91A may be formed in the openings, respectively. Through this, the first material layers 91 may be replaced with the third material layers 91A, and a gate structure GST including the third material layers 91A and the second material layers 92 that are alternately stacked may be formed. Subsequently, a slit structure 100 may be formed in the slit SL. The slit structure 100 may include at least one of an insulating material, a semiconductor material and a conductive material.

Subsequently, the hard mask pattern 97 may be removed. Through this, the rear surface RS of the gate structure GST may be exposed. The channel structure CH may protrude from the rear surface RS of the gate structure GST. As an example, at least one of the second supports 98, the channel structures CH, the second isolation structure 99, or the slit structure 100 may protrude from the rear surface RS of the gate structure GST.

Subsequently, a source structure 101 may be formed. As an example, a conductive layer may be formed and the source structure 101 may be formed by etching the conductive layer. At least one of the second supports 98, the channel structures CH, the second isolation structure 99, or the slit structure 100 may protrude into the source structure 101. Subsequently, an insulating layer 102 may be formed.

According to the manufacturing method described above, the first supports 93 may be formed when the first wafer WF1 is formed, and the second supports 98 may be formed after wafer bonding. After the wafer bonding, the first material layers 91 may be replaced with third material layers 91A. The second isolation structure 99 may be further formed after the wafer bonding. Accordingly, the manufacturing process of the semiconductor device can be improved.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including stacked gate lines and having a step structure;
an interlayer dielectric layer covering the step structure;
first supports extending through the interlayer dielectric layer and the gate structure;
contact plugs extending through the interlayer dielectric layer, wherein each of the contact plugs is connected to the gate lines exposed through the step structure, respectively; and
second supports extending through the gate structure, each of the second supports being located between the first supports.

2. The semiconductor device of claim 1, wherein the first supports extend into the gate structure through a front surface of the gate structure, and wherein the second supports extend into the gate structure through a rear surface of the gate structure.

3. The semiconductor device of claim 1, wherein the first supports each have a tapered or bowing cross section, and wherein the second supports each have a tapered shape in a reverse direction with respect to the first supports.

4. The semiconductor device of claim 1, wherein the contact plugs each have a tapered cross section, and wherein the second supports each have a tapered shape in a reverse direction with respect to the contact plugs.

5. The semiconductor device of claim 1, wherein the second supports are located to face the contact plugs.

6. The semiconductor device of claim 1, wherein a first contact plug among the contact plugs is connected to a first gate line among the gate lines, and wherein a second support of the second supports is located to face the first contact plug with the first gate line interposed between the second support and the first contact plug.

7. The semiconductor device of claim 1, wherein a first contact plug among the contact plugs is connected to a lower surface of a first gate line among the gate lines, and wherein a second support of the second supports is connected to an upper surface of the first gate line.

8. The semiconductor device of claim 1, further comprising:
a source structure located on the gate structure.

9. The semiconductor device of claim 8, wherein the second supports extend into the source structure.

10. The semiconductor device of claim 8, further comprising:
a channel structure extending into the source structure through the gate structure.

11. The semiconductor device of claim 10, wherein, among the contact plugs, a contact plug closer to the channel layer has a higher height than the other contact plug, and
wherein, among the second supports, a second support closer to the channel structure has a smaller height than the other second support.

12. The semiconductor device of claim 10, wherein among the contact plugs, a contact plug closer to the channel structure has a smaller height than the other contact plug, and
wherein, among the second supports, a second support closer to the channel structure has a larger height than the other second support.

13. A semiconductor device comprising:
a gate structure including stacked gate lines;
first supports extending into the gate structure through a front surface of the gate structure;
contact plugs extending into the gate structure through the front surface of the gate structure, the contact plugs electrically connected to the gate lines, respectively; and
second supports extending into the gate structure through a rear surface of the gate structure, each of the second supports being located between the first supports.

14. The semiconductor device of claim 13, further comprising:
insulation spacers surrounding sidewalls of the contact plugs.

15. The semiconductor device of claim 13, wherein the first supports each have a tapered or bowing cross section, and wherein the second supports each have a tapered shape in a reverse direction with respect to the first supports.

16. The semiconductor device of claim 13, wherein the contact plugs each have a tapered cross section, and wherein the second supports each have a tapered shape in a reverse direction with respect to the contact plugs.

17. The semiconductor device of claim 13, further comprising:
a source structure located on the gate structure,
wherein the second supports extend into the source structure.

18. The semiconductor device of claim 13, further comprising:
a source structure located on the gate structure; and
a channel structure extending into the source structure through the gate structure.

19. A manufacturing method of a semiconductor device, the manufacturing method comprising:
forming a stack including first material layers and second material layers that are alternately stacked;
forming first supports extending into the stack through a front surface of the stack;
forming contact plugs respectively connected to the first material layers through the front surface of the stack; and
forming second supports extending into the stack through a rear surface of the stack.

20. The manufacturing method of claim 19, further comprising:
forming a slit extending into the stack through the rear surface of the stack; and
replacing the first material layers with conductive layers through the slit.

21. The manufacturing method of claim 19, wherein the contact plugs are located between the first supports.

22. The manufacturing method of claim 19, wherein the second supports are located between the first supports.

23. The manufacturing method of claim 19, wherein the second supports are located to face the first support with at least one first material layer interposed between the second support and the first support.

24. The manufacturing method of claim 19, wherein forming the second supports comprises:
forming, on the rear surface of the stack, a hard mask pattern including openings;
forming, on the hard mask pattern, a mask exposing at least one opening; and
etching the stack using the mask and the hard mask pattern as etching barriers.

25. The manufacturing method of claim 24, further comprising:
reducing the mask; and
etching the stack using the hard mask pattern and the reduced mask as etching barriers to extend the openings into the stack so that the first material layers are respectively exposed.

26. The manufacturing method of claim 24, further comprising:
removing the hard mask pattern; and
forming a source structure on the rear surface of the stack.

27. The manufacturing method of claim 19, further comprising:
forming a slit extending into the stack through the rear surface of the stack; and
replacing the first material layers with third material layers through the slit.

28. A manufacturing method of a semiconductor device, the manufacturing method comprising:
forming a first wafer including a stack, wherein the stack includes first material layers and second material layers that are alternately stacked on a substrate;
bonding the first wafer and the second wafer;
exposing a rear surface of the stack by removing the substrate;
forming first supports extending into the stack through the rear surface; and
replacing the first material layers with third material layers.

29. The manufacturing method of claim 28, wherein forming the first wafer comprises:
forming contact plugs connected to the first material layers, respectively.

30. The manufacturing method of claim 29, wherein the contact plugs extend into the stack through a front surface of the stack.

31. The manufacturing method of claim 29, wherein the contact plugs are respectively connected to the first material layers stacked in a step shape.

32. The manufacturing method of claim 28, wherein forming the first wafer comprises:
forming second supports extending into the stack through the front surface of the stack.

33. The manufacturing method of claim 28, wherein forming the first supports comprises:
forming openings respectively exposing the first material layers; and
forming the first supports in the openings, respectively.

34. The manufacturing method of claim 28, wherein forming the first supports comprises:
forming openings having different depths in the stack; and
forming the first supports in the openings, respectively.

35. The manufacturing method of claim 34, wherein forming the openings having different depths comprises:
forming, on the stack, a hard mask pattern including openings;
forming a mask pattern exposing at least one of the openings;
etching the stack using the mask pattern and the hard mask pattern as etching barriers;
reducing the mask pattern; and
forming the openings by etching the stack using the hard mask pattern and the reduced mask pattern as etching barriers.
